(19) United States
(12) Patent Application Publication
(10) Pub. No.: US 2026/0344253 A1
(43) Pub. Date: Oct. 29, 2026

(54) DISPLAY MODULE AND DISPLAY DEVICE

(71) Applicant: Xiamen Tianma Display Technology Co., Ltd., Xiamen (CN)

(72) Inventors: Fang WAN, Xiamen (CN); Guangbing SUN, Xiamen (CN); Liuijng FAN, Xiamen (CN); Kang YANG, Xiamen (CN)

(21) Appl. No.: 19/259,516

(22) Filed: Jul. 3, 2025

(30) Foreign Application Priority Data
Apr. 28, 2025 (CN) 202510549539.0

(51) Int. Cl. H10K 59/80; H10K 102/00

(52) U.S. Cl. CPC H10K 59/8722; H10K 59/8792; H10K 59/8793; H10K 2102/311

(57) ABSTRACT

The present disclosure discloses a display module, where the display module includes a display panel, a protective cover plate located on a display side of the display panel, a first adhesive layer located between the display panel and the protective cover plate. A first region of the protective cover plate is a light-transmitting region, and a second region of the protective cover plate is a non-light-transmitting region. The first adhesive layer includes at least one groove, and in a direction perpendicular to a plane of the display module, the second region of the protective cover plate covers the at least one groove. When the display module is in a bent state, the display module includes a bending region and a non-bending region, and in the direction perpendicular to the plane of the display module, the at least one groove at least partially overlaps with the bending region.

### CROSS-REFERENCE S TO RELATED APPLICATION S

The present disclosure claims priority to Chinese Patent Application No. 202510549539.0, filed on Apr. 28, 2025, the content of which is incorporated herein by reference in its entirety.

### TECHNICAL FIELD

The present disclosure relates to the field of display technologies, and more specifically, relates to a display module and a display device.

### BACKGROUND

With the rapid advancement of flexible display technologies, the application of flexible display screens has become increasingly widespread and has been gradually adopted in various display devices. However, in existing bendable display devices, within the bending region, a flexible film located on the display side of the flexible display screen tends to delaminate from the flexible display screen, thereby adversely affecting the reliability of the display device and, consequently, degrading the user experience.

### SUMMARY

One aspect of the present disclosure provides a display module, where the display module includes a display panel, a protective cover plate located on a display side of the display panel, a first adhesive layer located between the display panel and the protective cover plate. A first region of the protective cover plate is a light-transmitting region, and a second region of the protective cover plate is a non-light-transmitting region, the second region surrounding the first region. The first adhesive layer includes at least one groove, and in a direction perpendicular to a plane where the display module is located, the second region of the protective cover plate covers the at least one groove. When the display module is in a bent state, the display module includes a bending region and a non-bending region, and in the direction perpendicular to the plane where the display module is located, the at least one groove at least partially overlaps with the bending region.

Another aspect of the present disclosure provides a display device. The display device includes a display module.

### BRIEF DESCRIPTION OF THE DRAWINGS

The above and other features, advantages, and aspects of the embodiments of the present disclosure will become more apparent by referring to the following detailed description in conjunction with the accompanying drawings. In the drawings, identical or similar reference numerals are used to denote identical or similar elements throughout. It should be understood that the drawings are illustrative and are not necessarily drawn to scale.

FIG. 1 illustrates a schematic structural diagram of a display module when an edge of an optical adhesive layer adopts a recessed design.

FIG. 2 illustrates a top view of a display module in a flattened state.

FIG. 3 illustrates a partial cross-sectional view of a display module in a bent state.

FIG. 4 illustrates a partial cross-sectional view of a display module before assembling a protective film, when an edge of an optical adhesive layer adopts an integrated edge-cutting design.

FIG. 5 illustrates a partial cross-sectional view of a display module after assembling a protective film, when an edge of an optical adhesive layer adopts an integrated edge-cutting design.

FIG. 6 illustrates a top view of an optical adhesive layer when an edge adopts an integrated edge-cutting design.

FIG. 7 illustrates a top view of a display module in a flattened state according to some embodiments of the present disclosure.

FIG. 8 illustrates another top view of a display module in a flattened state according to some embodiments of the present disclosure.

FIG. 9 illustrates a partial cross-sectional view of a display module according to some embodiments of the present disclosure.

FIG. 10 illustrates a partial cross-sectional view of a display module in a bent state according to some embodiments of the present disclosure.

FIG. 11 illustrates yet another top view of a display module in a flattened state according to some embodiments of the present disclosure.

FIG. 12 illustrates still another top view of a display module in a flattened state according to some embodiments of the present disclosure.

FIG. 13 illustrates yet another top view of a display module in a flattened state according to some embodiments of the present disclosure.

FIG. 14 illustrates another partial cross-sectional view of a display module according to some embodiments of the present disclosure.

FIGS. 15 to 17 illustrate schematic diagrams of a formation process of a first adhesive layer in a display module according to some embodiments of the present disclosure.

FIG. 18 illustrates yet another schematic diagram of a formation process of a first adhesive layer in a display module according to some embodiments of the present disclosure.

FIG. 19 illustrates yet another partial cross-sectional view of a display module according to some embodiments of the present disclosure.

FIG. 20 illustrates still another partial cross-sectional view of a display module according to some embodiments of the present disclosure.

FIG. 21 illustrates a partial cross-sectional view of a display panel in the display module according to some embodiments of the present disclosure.

FIG. 22 illustrates a schematic diagram of a display device according to some embodiments of the present disclosure.

### DETAILED DESCRIPTION

The embodiments of the present disclosure will be described clearly and completely below with reference to the accompanying drawings. It is apparent that the described embodiments are merely part of the embodiments of the present disclosure and not all of the embodiments. All other embodiments obtained by those skilled in the art without creative effort, based on the embodiments of the present disclosure, are intended to fall within the scope of protection of the present disclosure.

Various modifications and variations of the present disclosure may be made without departing from the spirit or scope of the present disclosure. Such modifications and variations will be apparent to those skilled in the art. Accordingly, the present disclosure is intended to cover all modifications and variations that fall within the scope of the appended claims and their equivalents. It should also be noted that, where there is no conflict, the features disclosed in different embodiments of the present disclosure may be combined with one another.

To make the objectives, features, and advantages of the present disclosure more apparent and understandable, the present disclosure will be further described in detail below with reference to the accompanying drawings and specific embodiments.

As described in the background section, in bendable display devices, a flexible film located on the display side of a flexible display screen tends to delaminate from the flexible display screen in the bending region, thereby reducing the reliability of the display device and degrading user experience.

Specifically, in practical applications, the flexible film located on the display side of the flexible display screen is typically bonded and fixed to the display side of the flexible display screen by an optical adhesive layer. Currently, to bond the flexible film to the display side of the flexible display screen using the optical adhesive layer, the edge of the optical adhesive layer typically adopts either a recessed design or an integrated edge-cutting design.

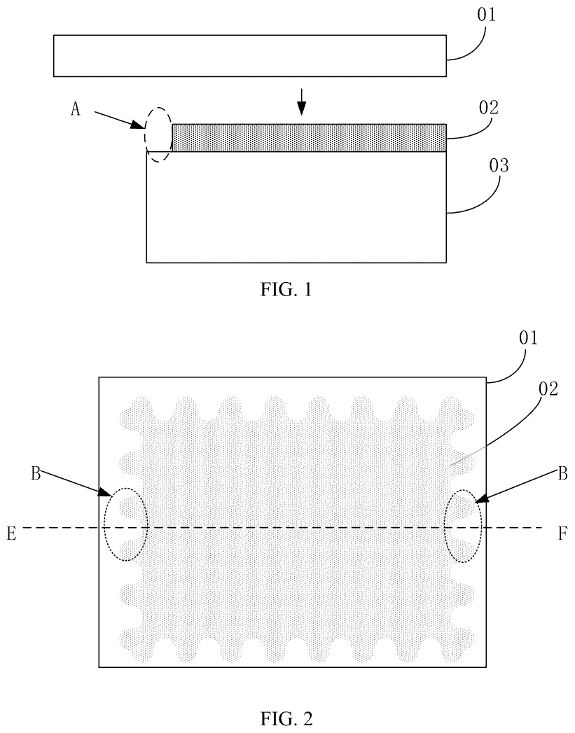

As shown in FIG. 1, when an edge of an optical adhesive layer 02 adopts a recessed design, and a flexible film 01 is laminated onto a surface of the optical adhesive layer 02, the edge of the optical adhesive layer 02 is located closer to the central region of a flexible display screen 03 than the edge of the flexible display screen 03. The recessed region of the optical adhesive layer 02 is illustrated as the dashed box region A in FIG. 1. However, during the lamination process, due to the non-uniform pressure distribution of the roller applying lamination force to the flexible film 01, the edge of the formed optical adhesive layer 02 tends to exhibit a wavy glue overflow, as shown in FIG. 2. Consequently, when the display device 04 is in a bent state, bending stress tends to concentrate at the “neck” of the bending region (i.e., the region with the smallest bending radius and greatest tensile stress), as illustrated in the dashed box region B of FIGS. 2 and 3, that is, the region in the bending region 042 of the display device 04 adjacent to the non-bending region 041. The stress concentration point typically coincides with the peak or valley of the wavy glue overflow in that region, resulting in crack initiation at the peak or valley. During repeated bending, such cracks may propagate both in a direction parallel to the plane of the flexible display panel and in a direction perpendicular to the plane of the flexible display panel, extending toward the display region of the display device. This causes the flexible film 01 to easily delaminate from the flexible display screen 03 in the bending region. If the cracks extend into the display region, they may further degrade the display quality of the display device.

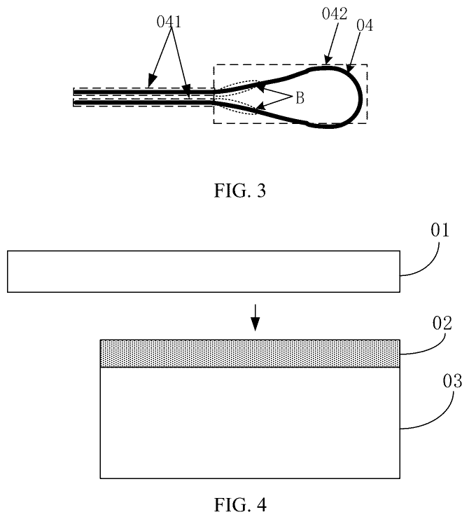

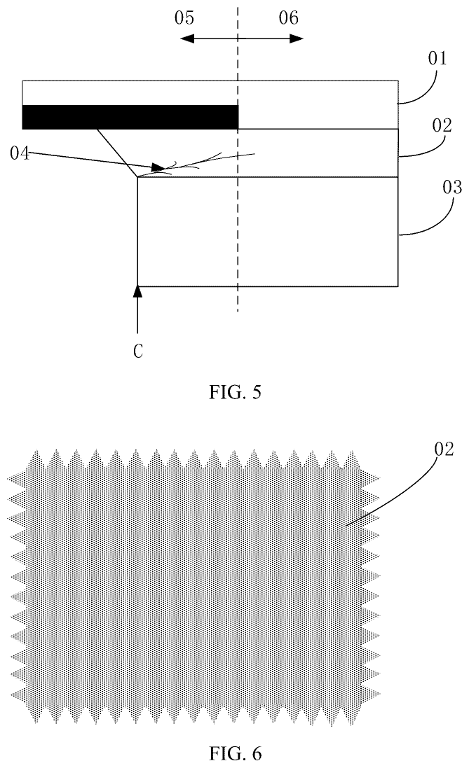

As shown in FIG. 4, when the edge of the optical adhesive layer 02 adopts an integrated edge-cutting design, prior to laminating the flexible film 01 onto a surface of the optical adhesive layer 02, the edge of the optical adhesive layer 02 is trimmed by a cutting process in a direction perpendicular to a planar display region of the flexible display screen 03, such that the edge of the optical adhesive layer 02 is flush with the edge of the flexible display screen 03. This is intended to address the issue of wavy glue overflow that may occur after the flexible film 01 is laminated onto the surface of the optical adhesive layer 02. However, as shown in FIG. 5, when a laser is used to cut the optical adhesive layer 02 at a cutting position C such that the edge of the optical adhesive layer 02 becomes flush with the edge of the flexible display screen 03 in a direction perpendicular to the planar display region of the flexible display screen 03, energy fluctuations in the laser may cause jagged edge defects at the boundary of the optical adhesive layer 02. As illustrated in FIG. 6, such jagged edge defects may act as stress concentration points during bending of the flexible display screen, resulting in the formation of cracks 04. During repeated bending, the crack 04 may propagate both in a direction parallel to the plane of the flexible display screen and in a direction perpendicular to the plane of the flexible display screen, extending toward the display region of the display device. This results in a high likelihood of delamination between the flexible film 01 and the flexible display screen 03 within the bending region. If the crack extends into the display region, it may further compromise the display quality of the display device.

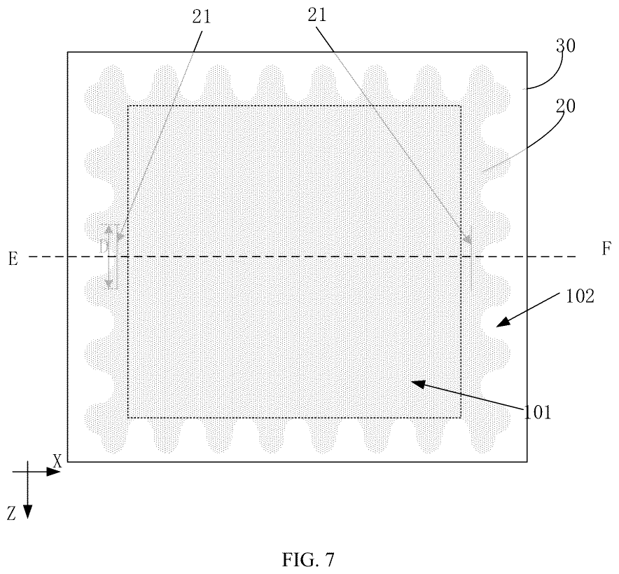

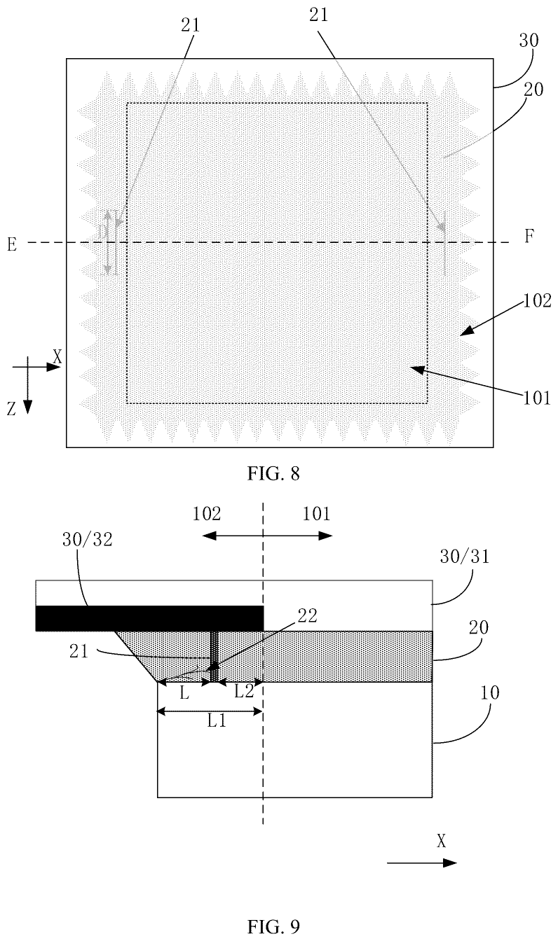

In view of the above, some embodiments of the present disclosure provide a display module. As shown in FIGS. 7 to 9, the display module includes:
a display panel 10;
a protective cover plate 30 located on a display side of the display panel 10, where a first region 101 of the protective cover plate 30 is a light-transmitting region, and a second region 102 is a non-light-transmitting region, the second region 102 surrounding the first region 101; and
a first adhesive layer 20 located between the display panel 10 and the protective cover plate 30, where the first adhesive layer 20 includes at least one groove 21, and in a direction perpendicular to a plane where the display module is located, the second region 102 of the protective cover plate 30 covers the at least one groove 21.

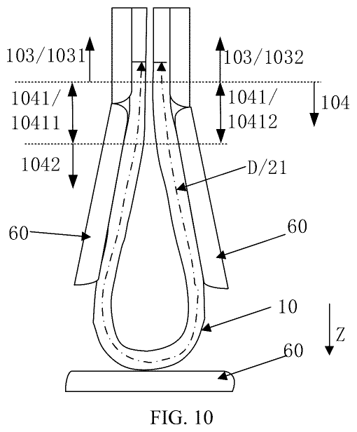

During the fabrication process of the display module, shape defects are likely to form at the edge of the first adhesive layer 20. As shown in FIG. 7, the edge of the first adhesive layer 20 may exhibit a wavy profile, or, as shown in FIG. 8, a jagged profile. The peaks or valleys of these edge defects may become stress concentration points when the display module is bent, leading to the formation of cracks. These cracks may propagate, during repeated bending, in both a direction parallel to the plane where the display module is located and a direction perpendicular to the plane where the display module is located, extending toward the light-transmitting region (i.e., the first region 101) of the display module. In the present embodiment, as shown in FIG. 10, when the display module is in a bent state, the display module includes a bending region 104 and a non-bending region 103. As illustrated in FIGS. 7 to 9, the portion of the first adhesive layer 20 corresponding to the non-light-transmitting region 102 includes at least one groove 21. In a direction perpendicular to the plane where the display module is located, the groove 21 at least partially overlaps with the bending region 104. During the bending process of the display module, the groove is able to block the propagation of cracks originating from shape defects at the edge of the first adhesive layer 20 from the non-light-transmitting region (i.e., the second region 102) toward the light-transmitting region (i.e., the first region 101). This reduces the likelihood of delamination between the protective cover plate 30 and the display panel 10 due to crack propagation, and ensures that the cracks in the first adhesive layer 20 do not extend into the light-transmitting region of the display module, thereby preventing degradation of display quality. This enhances the bending reliability of the display module and improves the user experience.

It should be noted that, although the accompanying drawings illustrate shape defects at the edge of the adhesive layer as wavy profiles (e.g., FIG. 7) or jagged profiles (e.g., FIG. 8), the present disclosure is not limited thereto. In other embodiments of the present disclosure, the edge of the adhesive layer may exhibit other types of shape defects or may be free of shape defects (e.g., when a side surface of the adhesive layer is planar), depending on the specific implementation.

In some embodiments of the present disclosure, and as further shown in FIG. 10, the display module may further include a hinge 60 located on a non-display side of the display panel 10. The hinge 60 is configured to assist in achieving smooth bending of the display panel 10 and to maintain the structural shape of the display panel 10. However, the present disclosure is not limited thereto and may be adjusted depending on the specific implementation.

On the basis of the above-described embodiments, in some embodiments of the present disclosure as further illustrated in FIG. 10, the bending region 104 of the display module includes a first bending region 1041 adjacent to the non-bending region 103, and a second bending region 1042 located on a side of the first bending region 1041 away from the non-bending region 103. Since, when the display module is bent, the stress concentration point tends to be located at the “neck” of the bending region—i.e., within the portion of the bending region 104 that is adjacent to the non-bending region 103. Accordingly, in some embodiments, the groove 21 overlaps with the first bending region 1041 in the direction perpendicular to the plane where the display module is located. By positioning the groove 21 near the stress concentration point that arises during the bending process of the display module, it is possible to further reduce the likelihood that cracks will be generated from the edge of the first adhesive layer 20 due to shape defects during bending of the display module. This suppresses crack propagation, both in a direction parallel to the plane of the display module and in a direction perpendicular to the plane of the display module, from the non-light-transmitting region toward the light-transmitting region of the display module. As a result, the probability of delamination between the protective cover plate 30 and the display panel 10 due to such crack propagation is reduced. At the same time, it ensures that cracks formed in the first adhesive layer 20 do not extend into the light-transmitting region of the display module, thereby affecting display quality of the display module, improving the bending reliability of the display module, and ultimately enhancing user experience.

Based on the above-described embodiments, in some embodiments of the present disclosure, the first bending region 1041 may include a stress concentration point region when the display module is in a bent state. This configuration is able to further reduce the likelihood that cracks will be generated from the edge of the first adhesive layer 20 due to shape defects during bending of the display module. It also suppresses the propagation of such cracks, in both a direction parallel to the plane of the display module and a direction perpendicular to the plane of the display module, from the non-light-transmitting region toward the light-transmitting region of the display module. As a result, the probability of delamination between the protective cover plate 30 and the display panel 10 due to crack propagation is reduced. At the same time, it ensures that cracks formed in the first adhesive layer 20 do not extend into the light-transmitting region of the display module, thereby affecting display quality of the display module, enhancing the bending reliability of the display module, and ultimately improving user experience.

Based on the above-described embodiments, in some embodiments of the present disclosure, the first bending region 1041 corresponds to a stress concentration region that arises during the bending process of the display module. In another embodiment of the present disclosure, the first bending region 1041 not only includes the stress concentration region but is also larger than the stress concentration region. This facilitates easier determination of the first bending region 1041. However, the present disclosure is not limited thereto, as long as the stress in the first bending region 1041 is greater than the stress in the second bending region 1042 when the display module is in a bent state.

Based on any of the above-described embodiments, in some embodiments of the present disclosure, the groove 21 extends along a direction from the first bending region 1041 to the second bending region 1042 and penetrates through the first bending region 1041. This configuration ensures that regardless of the specific location of a crack—originating from a shape defect at the edge of the first adhesive layer 20—within the first bending region 1041 during bending of the display module, the groove 21 is able to block the crack from propagating from the non-light-transmitting region to the light-transmitting region of the display module. However, the present disclosure is not limited thereto, as long as the groove 21 extends through at least the stress concentration region of the display module along the direction from the first bending region 1041 to the second bending region 1042 when the display module is in a bent state.

It should be noted that, in practical applications, the display module may be a single-fold display module, i.e., a display module having one bending axis, or a dual-fold display module having two bending axes. The display module may also have more bending axes.

Accordingly, based on any of the above-described embodiments, in some embodiments of the present disclosure, as shown in FIGS. 7-8 and FIGS. 11-12, the display module includes at least one bending axis EF. In the present embodiment, the bending axis EF extends in a first direction X, and the groove 21 extends in a second direction Y, where the first direction X and the second direction Y are different. As a result, the extending direction of the groove 21 intersects with the extending direction of the bending axis EF, which facilitates blocking, by means of the groove 21, the propagation of cracks generated from shape defects at the edge of the first adhesive layer 20 located near the bending axis region of the display module, from the non-light-transmitting region toward the light-transmitting region during bending of the display module. This configuration improves the bending reliability of the display module. The first direction X and the second direction Y may be perpendicular to each other, such that while maintaining a constant length of the groove 21 in the direction perpendicular to the first direction X, the dimension of the groove 21 in the second direction Y may be reduced. This ensures that the groove is confined within the non-light-transmitting region of the display module and does not extend into the light-transmitting region.

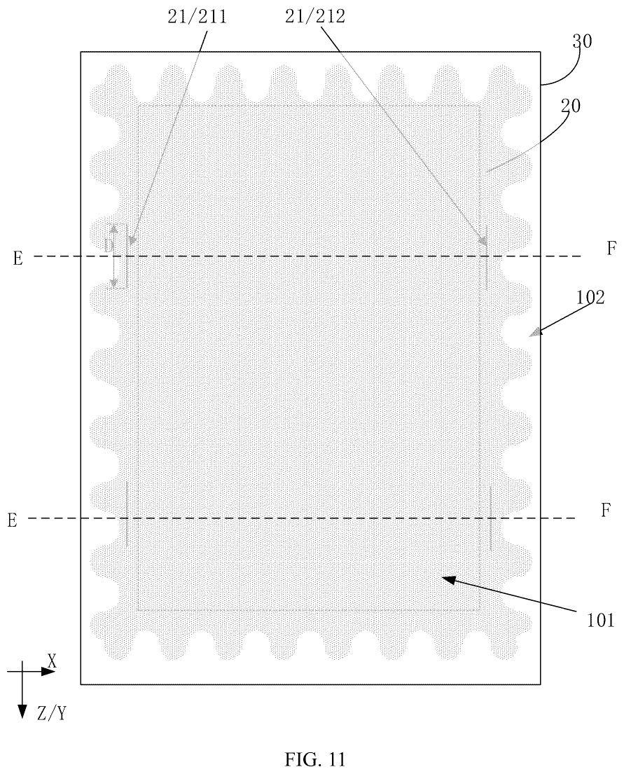

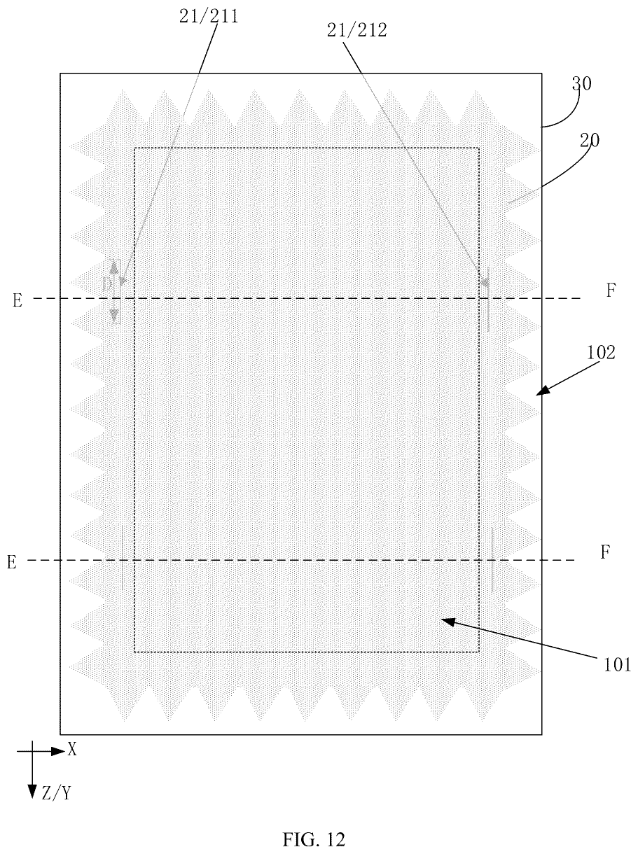

Based on the above-described embodiments, in some embodiments of the present disclosure, as shown in FIGS. 11 and 12, the display module includes N bending axes EF. As disclosed herein, the first adhesive layer 20 includes N sets of grooves 21, where the N sets of grooves 21 are arranged in a direction perpendicular to the first direction X, and each set of grooves 21 corresponds to one bending axis EF. Each set of grooves 21 includes at least one groove 21, and N is an integer not less than 1. By respectively providing grooves 21 corresponding to the regions where each bending axis EF is located, cracks originating from the edge of the first adhesive layer 20 during bending at each bending axis region may be blocked from propagating, in both a direction parallel to the plane of the display module and a direction perpendicular to the plane of the display module, from the non-light-transmitting region toward the light-transmitting region.

As further illustrated in FIGS. 11 and 12, in some embodiments, each set of grooves 21 includes a first groove 211 and a second groove 212, where the first groove 211 and the second groove 212 are oppositely arranged along the second direction. Specifically, the first groove 211 is located on a first side of the light-transmitting region (i.e., the first region 101) of the display module, and the second groove 212 is located on a second side of the light-transmitting region, where the first side and the second side are on opposite sides of the light-transmitting region in the first direction X. In this way, during bending of the display module in the region where the bending axis is located, cracks generated from the edge of the first adhesive layer may be blocked from both sides of the bending axis from propagating, in directions both parallel and perpendicular to the plane of the display module, from the non-light-transmitting region toward the light-transmitting region, thereby further enhancing the bending reliability of the display module.

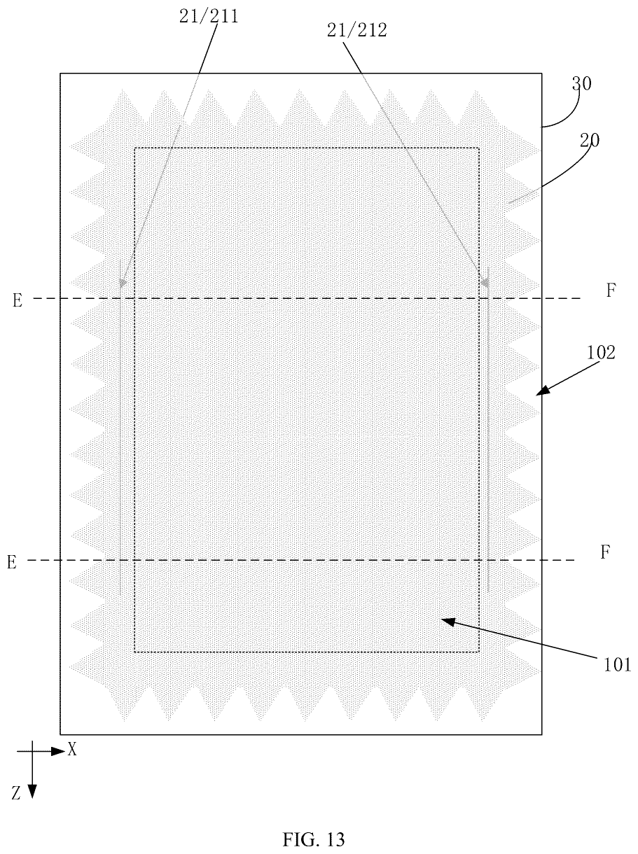

In some embodiments of the present disclosure, as shown in FIG. 13, the display module includes N bending axes EF, and a set of grooves 21 is arranged in the first adhesive layer 20. The same set of grooves 21 is used to block cracks generated from the edge of the first adhesive layer 20 during bending in regions corresponding to each of the bending axes EF, from propagating, in directions both parallel and perpendicular to the plane of the display module, from the non-light-transmitting region toward the light-transmitting region. This enhances the bending reliability of the display module. However, the present disclosure is not limited thereto and may be adapted as appropriate depending on the specific implementation.

In the following, a display module is described by way of example in which the display module includes N bending axes, and the first adhesive layer 21 includes N sets of grooves, with each set of grooves corresponding to one bending axis.

In some embodiments of the present disclosure, and as shown in FIGS. 7-8 and FIGS. 11-12, the groove 21 has a length D in a third direction Z that satisfies D≥2×D₀+first process tolerance, where the first process tolerance includes a process tolerance associated with the formation of the groove 21, and D₀ is not less than the length of the first bending region 1041 in the third direction Z. The third direction Z is perpendicular to the first direction X. This configuration ensures that, within allowable manufacturing tolerances, the length of the groove 21 is sufficient to block cracks generated from the edge of the first adhesive layer 20 during bending of the display module, which may otherwise propagate—both in directions parallel and perpendicular to the plane of the display module—from the non-light-transmitting region toward the light-transmitting region, thereby enhancing the bending reliability of the display module.

Based on the foregoing embodiments, in some embodiments of the present disclosure, the first process tolerance further includes an alignment tolerance generated during formation of the first adhesive layer 20, as well as an assembly tolerance that may arise when the display module is assembled into the display device. This ensures that the groove 21 is of sufficient length to block cracks generated from the edge of the first adhesive layer when the display module is in a bent state from propagating from the non-light-transmitting region of the display module to the light-transmitting region of the display module along the direction parallel to the plane where the display module is located and perpendicular to the plane where the display module is located, thereby improving the bending reliability of the display module.

It should be noted, as further illustrated in FIG. 9, when the first adhesive layer 20 bonds the display panel 10 and the protective cover plate 30, the first adhesive layer 20 is first formed on the display side of the display panel 10. The protective cover plate 30 is then bonded onto a side of the first adhesive layer 20 away from the display panel 10. Cracks 22 generated from the edge of the first adhesive layer 20 during bending typically initiate from the side facing the display panel 10. Therefore, in some embodiments of the present disclosure, the alignment tolerance during formation of the first adhesive layer 20 refers to the alignment tolerance when the first adhesive layer 20 is bonded to the display panel 10, but does not include the alignment tolerance when the first adhesive layer 20 is bonded to the protective cover plate 30. However, the present disclosure is not limited thereto and may be adjusted depending on the specific implementation.

In some embodiments of the present disclosure, the alignment tolerance during formation of the first adhesive layer 20 is in the range of 0.1 mm to 0.2 mm, the process tolerance for forming the groove 21 is approximately 0.1 mm, and the assembly tolerance during integration of the display module into the display device is in the range of 0.1 mm to 0.3 mm. However, the present disclosure is not limited thereto and may be adjusted depending on the specific implementation.

It should also be noted that, as disclosed herein, the second direction and the first direction may be perpendicular or non-perpendicular. If the second direction is perpendicular to the first direction, as shown in FIGS. 11 and 12, the third direction Z and the second direction Y are the same. If the second direction is not perpendicular to the first direction, the third direction differs from the second direction and corresponds to the component of the second direction that is perpendicular to the first direction.

In some embodiments of the present disclosure, the length D of the groove 21 in the third direction Z is in the range of 5 mm to 30 mm, so as to ensure that the groove is long enough to fully block cracks generated from the edge of the first adhesive layer 20 during the bending process of the display module from the non-light-transmitting region to the light-transmitting region of the display module, and to avoid the length D of the groove 21 in the third direction Z being too large, which affects the flatness of the first adhesive layer. However, the present disclosure is not limited thereto and may be adjusted depending on the specific implementation.

In the above-described embodiments, the center of the groove 21 in the third direction Z coincides with the center of the first bending region 1041 in the third direction. This allows the groove 21 to block cracks generated from the edge of the first adhesive layer 20 when the display module is in a bent state—both in directions parallel and perpendicular to the display plane—from propagating from the non-light-transmitting region to the light-transmitting region, while minimizing the length of the groove 21 in the third direction. However, the present disclosure is not limited thereto and may be adjusted depending on the specific implementation.

Based on the foregoing embodiments, in some embodiments of the present disclosure, D₀ is defined as the length of the first bending region 1041 in the third direction Z, so that the setting of the groove 21 may block cracks generated from the edge of the first adhesive layer 20 during bending of the display module from propagating from the non-light-transmitting region toward the light-transmitting region along the direction parallel to the plane where the display module is located and perpendicular to the plane where the display module is located. At the same time, the length of the groove 21 in the third direction may be minimized. However, the present disclosure is not limited thereto and may be adjusted depending on the specific implementation.

On the basis of any of the above embodiments, in some embodiments of the present disclosure as further illustrated in FIG. 10, the non-bending region 103 of the display module includes a first planar display region 1031 and a second planar display region 1032. The bending region 104 is located between the first planar display region 1031 and the second planar display region 1032 in a direction parallel to the display surface of the display panel. The first bending region 1041 includes a first sub-bending region 10411 and a second sub-bending region 10412. The first sub-bending region 10411 is located between the first planar display region 1031 and the second bending region 1042, and the second sub-bending region 10412 is located between the second planar display region 1032 and the second bending region 1042. It should be noted that, as disclosed herein, neither the first sub-bending region 10411 nor the second sub-bending region 10412 overlaps with the bending axis of the bending region 104. D₀ is not less than the distance from the side of the first sub-bending region 10411 that faces away from the second sub-bending region 10412 to the side of the second sub-bending region 10412 that faces away from the first sub-bending region 10411. This ensures that the groove 21, extending from the non-bending region 103 toward the bending region 104, passes entirely through the bending region 104. Therefore, regardless of the specific location within the bending region where a crack is generated from the edge of the first adhesive layer during bending of the display module, the groove 21 is able to block the propagation of the crack—both in a direction parallel to the plane of the display module and in a direction perpendicular to the plane of the display module—from the non-light-transmitting region toward the light-transmitting region. However, the present disclosure is not limited thereto and may be adapted as appropriate depending on the specific implementation.

It should be noted that during the manufacturing process of the display module, process tolerances are inevitable. For example, when the first adhesive layer 20 is formed on the display side of the display panel 10, there may be an alignment tolerance between the first adhesive layer 20 and the display panel 10. In some embodiments of the present disclosure, the first adhesive layer 20 includes the groove 21 prior to being bonded to the display side of the display panel 10, i.e., the groove 21 is formed in the first adhesive layer 20 in advance, and then the first adhesive layer 20 is bonded to the display side of the display panel 10.

Accordingly, based on any of the foregoing embodiments, and as shown in FIG. 9, in some embodiments of the present disclosure, the distance L between the groove 21 and the edge of the first adhesive layer 20 satisfies L≥L₀, where L₀ is a value corresponding to a second process tolerance. The second process tolerance includes the alignment tolerance during formation of the first adhesive layer 20. This ensures that, after the first adhesive layer 20 is formed on the display side of the display panel 10, the groove 21 is not partially or completely cut off when a laser is used to trim the edge of the first adhesive layer 20 at a cutting position C. On the condition that the groove 21 will not be removed during laser cutting of the edge of the first adhesive layer 20 at cutting position C, the probability that the groove 21 overlaps with the edge of the display panel 10 is reduced. This helps prevent situations in which the placement of the groove 21 fails to block cracks generated in the overlapping region between the edge of the first adhesive layer 20 and the edge of the display panel 10 during bending of the display module, where such cracks would otherwise propagate—both in a direction parallel to the plane of the display module and a direction perpendicular to the plane of the display module—from the non-light-transmitting region toward the light-transmitting region.

As previously described, when the first adhesive layer 20 is used to bond the display panel 10 and the protective cover plate 30, the first adhesive layer 20 is first formed on the display side of the display panel 10, and the protective cover plate 30 is subsequently bonded to the side of the first adhesive layer 20 away from the display panel 10. Since the starting point of the jagged defect 22 of the first adhesive layer 20 is located on the side of the first adhesive layer 20 facing the display panel 10, in some embodiments of the present disclosure, the alignment tolerance during formation of the first adhesive layer 20 refers to the alignment tolerance between the first adhesive layer 20 and the display panel 10 during bonding, and does not include the alignment tolerance between the first adhesive layer 20 and the protective cover plate 30 during bonding. However, the present disclosure is not limited thereto and may be adjusted depending on the specific implementation.

It should also be noted that process tolerance may also occur during the formation of the groove 21. Therefore, based on the above embodiments, in some embodiments of the present disclosure, the second process tolerance further includes a process tolerance associated with the formation of the groove 21, so as to further reduce the probability that the position of the groove 21 overlaps with the edge of the display panel 10 when the first adhesive layer 20 is formed on the display side of the display panel 10. This prevents situations in which the groove 21 fails to block cracks generated in the overlapping region between the first adhesive layer 20 and the edge of the display panel 10 during bending of the display module, where such cracks would otherwise propagate from the non-light-transmitting region toward the light-transmitting region of the display module.

In some embodiments of the present disclosure, the alignment tolerance during formation of the first adhesive layer 20 is in the range of 0.1 mm to 0.2 mm, and the process tolerance associated with the formation of the groove 21 is approximately 0.1 mm. However, the present disclosure is not limited thereto and may be adjusted as appropriate depending on the specific implementation.

In some embodiments of the present disclosure, as shown in FIG. 9, the distance L₂ between the groove 21 and the light-transmitting region of the display module (i.e., the first region 101 of the display module) in the first direction X satisfies L₂≥L₀, where L₀ is a value corresponding to the second process tolerance, and the second process tolerance includes the alignment tolerance during formation of the first adhesive layer 20. This configuration reduces the probability that the position of the groove 21 overlaps with the display region of the display panel 10 when the first adhesive layer 20 is formed on the display side of the display panel 10. This helps prevent situations in which the groove 21 is unable to block cracks generated at the overlapping region between the edge of the first adhesive layer 20 and the edge of the display panel 10 during bending of the display module from propagating from the non-light-transmitting region toward the light-transmitting region. It also avoids scenarios where the groove 21 is at least partially located within the light-transmitting region of the display module, and thus visible to the user.

Based on any of the foregoing embodiments, in some embodiments of the present disclosure, and as further shown in FIG. 9, the width of the overlapping region between the second region 102 of the protective cover plate 30 and the first adhesive layer 20 in the first direction X is L₁, and L=L₁/2. This configuration ensures that the position of the groove 21 is capable of blocking cracks generated in the overlapping region between the first adhesive layer 20 and the edge of the display panel 10 during bending of the display module from propagating from the non-light-transmitting region toward the light-transmitting region. At the same time, it reduces the width of the overlapping region between the second region 102 of the protective cover plate 30 and the first adhesive layer 20 in the first direction X, which facilitates the implementation of a narrow-bezel display module.

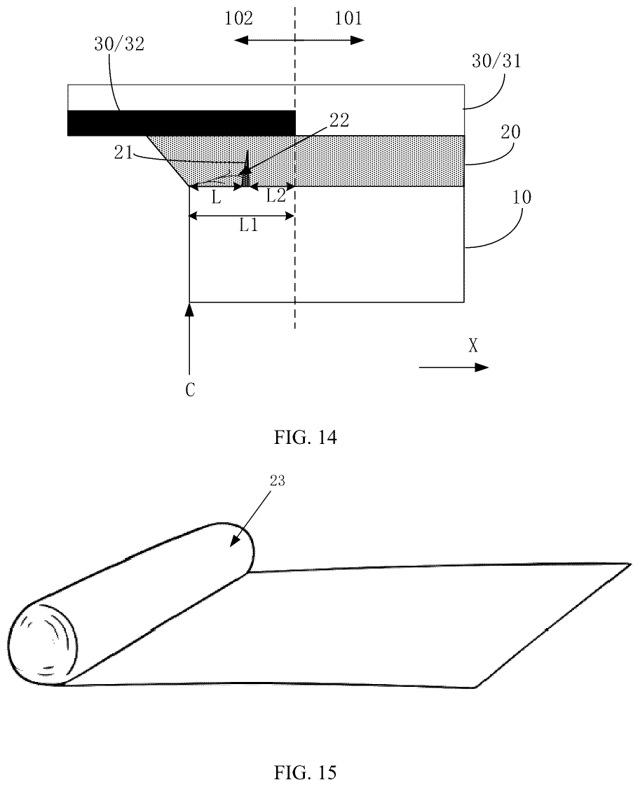

It should be noted that the first adhesive layer 20 is typically very thin. Accordingly, in any of the above embodiments and as shown in FIG. 9, the groove 21 penetrates through the first adhesive layer 20, so as to reduce the manufacturing complexity of the groove 21 while ensuring that the position of the groove 21 is capable of blocking cracks generated in the overlapping region between the first adhesive layer 20 and the edge of the display panel 10 during bending of the display module from propagating from the non-light-transmitting region toward the light-transmitting region. However, the present disclosure is not limited thereto. In other embodiments of the present disclosure, the groove 21 may not penetrate through the first adhesive layer 20, as shown in FIG. 14, depending on the specific implementation.

In some embodiments of the present disclosure, the groove 21, as shown in the cross-sectional view of the display module, may have a rectangular shape, as further illustrated in FIG. 9, a wedge shape, as shown in FIG. 14, or a trapezoidal shape, or may take other shapes. The present disclosure is not limited to any particular groove geometry and may vary depending on the specific implementation.

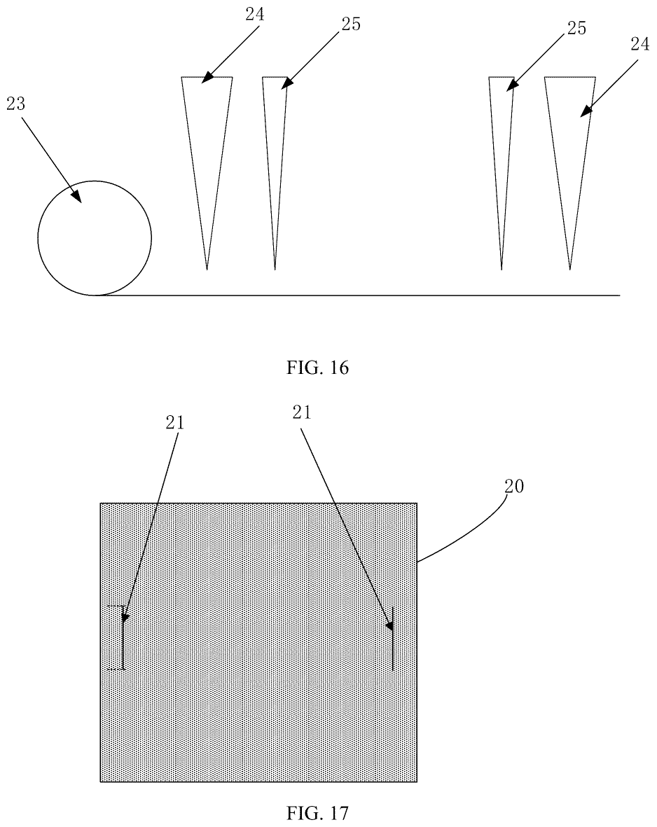

Based on any of the above embodiments, in some embodiments of the present disclosure, the groove 21 is formed by a physical cutting process, so as to avoid the generation of shape defects at the groove 21 location during the formation of the groove 21 in the first adhesive layer 20. The groove 21 may be formed using a die-cutting process. Specifically, as shown in FIG. 15, a roll of adhesive film 23 is first unwound from its trailing end over a certain length such that at least a portion of the adhesive film 23 is laid flat starting from the trailing end. Then, as shown in FIG. 16, a first die 24 and a second die 25 are used to perform die-cutting on the flattened portion of the adhesive film 23. The first die is used to form a first adhesive layer 20 having a fixed size, and the second die 25 is used to form the groove 21, thereby obtaining a first adhesive layer 20 with a groove 21, as shown in FIG. 17. After obtaining the first adhesive layer 20 with the groove 21, it is bonded to the display side of the display panel 10, and subsequently, the protective cover plate 30 is bonded to the side of the first adhesive layer 20 away from the display panel 10.

Based on any of the above embodiments, in some embodiments of the present disclosure, the display module further includes a filling layer for filling the groove, where the filling layer contains a crack-arresting agent. This enhances the effectiveness of the groove in blocking the propagation of cracks generated at the edge of the first adhesive layer during bending of the display module, further preventing such cracks from propagating from the non-light-transmitting region toward the light-transmitting region, thereby improving the bending reliability of the display module.

In some embodiments of the present disclosure, the crack-arresting agent may be an epoxy-polyamide primer, a polysulfide sealant, etc. The present disclosure is not limited thereto and may vary depending on the specific implementation.

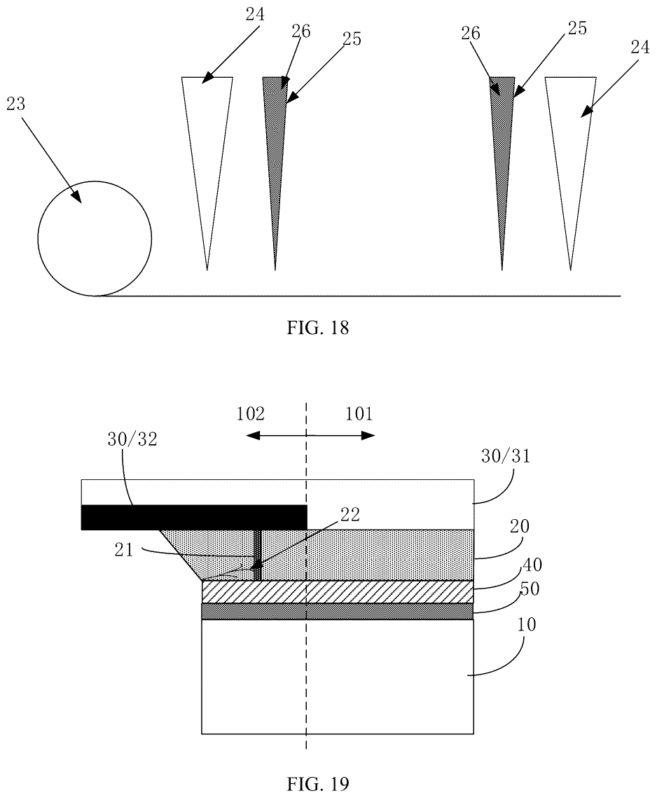

Based on the above embodiments, in some embodiments of the present disclosure, the process of filling the groove with the crack-arresting agent may be performed simultaneously with the formation of the groove in the first adhesive layer using a die-cutting tool. For example, as shown in FIG. 18, a crack-arresting agent 26 may be preloaded into the second die 25. When the second die 25 is used to punch the adhesive film 23, the crack-arresting agent 26 is filled into the groove formed by the second die 25. This configuration avoids increasing the process complexity of the display module due to the addition of the crack-arresting agent.

In some embodiments of the present disclosure, prior to being formed on the display side of the display panel 10, the first adhesive layer 20 is in a liquid state. As disclosed herein, the formation process of the groove 21 includes: first placing a groove-forming jig at a target location on the display side of the display panel 10 where the groove 21 is to be formed; then applying the first adhesive layer 20 onto the display side of the display panel 10 and curing the first adhesive layer 20; and finally, after curing, removing the groove-forming jig from the cured first adhesive layer 20 to form the groove 21 in the first adhesive layer 20.

Based on the above embodiments, in some embodiments of the present disclosure, the display module further includes a filling layer for filling the groove, where the filling layer contains a crack-arresting agent. The presence of the crack-arresting agent enhances the effectiveness of the groove in blocking the propagation of cracks generated at the edge of the first adhesive layer during bending of the display module, further preventing such cracks from propagating from the non-light-transmitting region toward the light-transmitting region, thereby improving the bending reliability of the display module. In some embodiments of the present disclosure, the crack-arresting agent may be an epoxy-polyamide primer, or a polysulfide sealant, etc. The crack-arresting agent positioned within the groove may be formed using a filling process. However, the present disclosure is not limited thereto and may vary depending on the specific implementation.

Based on any of the above embodiments, in some embodiments of the present disclosure, and as further shown in FIG. 9, the protective cover plate 30 includes a transparent film 31 and a light-shielding layer 32 located in a partial region of the side of the transparent film 31 facing the display panel 10. The light-shielding layer 32 corresponds to the second region 102 of the protective cover plate 30, so as to absorb light directed toward the second region 102 of the protective cover plate 30, thereby rendering the second region 102 a non-light-transmitting region.

In some embodiments of the present disclosure, the transparent film is a flexible film, such as a colorless polyimide (CPI) film or other transparent flexible film. The light-shielding layer is an ink layer or other light-absorbing layer. The present disclosure is not limited thereto, and specific implementations may vary depending on the circumstances.

Based on any of the above embodiments, in some embodiments of the present disclosure, as shown in FIG. 19, the display module includes a polarizer 40 located between the display panel 10 and the protective cover plate 30. The polarizer 40 is configured to reduce light reflection on the display surface of the display module and improve the display quality of the display module. However, the present disclosure is not limited thereto. In other embodiments, as further shown in FIG. 9, the display panel 10 and the protective cover plate 30 may be configured without a polarizer 40, in order to reduce the overall thickness of the display module, depending on specific implementation requirements.

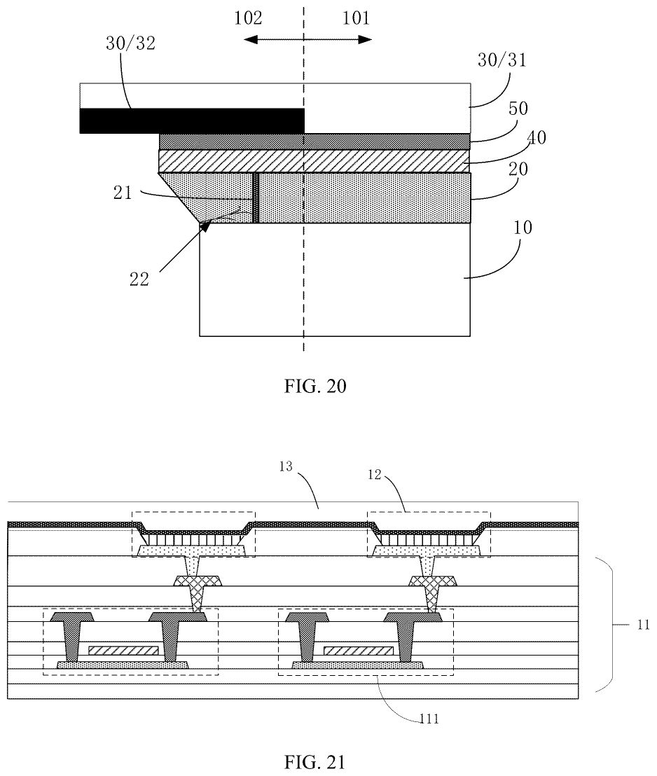

In some embodiments of the present disclosure, as further illustrated in FIG. 19, the display module includes a polarizer 40 located between the display panel 10 and the protective cover plate 30. The polarizer 40 is bonded to the protective cover plate 30 via a first adhesive layer 20 and is bonded to the display panel 10 via a second adhesive layer 50. As illustrated in FIG. 20, the display module includes a polarizer 40 located between the display panel 10 and the protective cover plate 30. The polarizer 40 is bonded to the protective cover plate 30 via a second adhesive layer 50, and is bonded to the display panel 10 via a first adhesive layer 20. However, the present disclosure is not limited thereto, and specific configurations may vary depending on actual implementation.

It should be noted that the polarizer may also be omitted between the display panel 10 and the cover plate 30. In such case, as shown in FIG. 9, the cover plate 30 is directly bonded to the display panel 10 via the first adhesive layer 20.

In some embodiments of the present disclosure, the first adhesive layer 20 may be an optical adhesive layer, and the second adhesive layer 50 may be a pressure-sensitive adhesive layer. However, the present disclosure is not limited thereto. In other embodiments of the present disclosure, the first adhesive layer 20 and the second adhesive layer 50 may both be optical adhesive layers or other types of adhesive layers, depending on specific requirements.

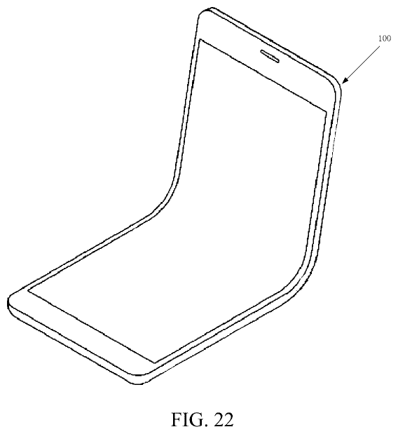

In some embodiments of the present disclosure, the display panel is an OLED display panel. As shown in FIG. 21, the display panel 10 includes: an array substrate 11; a plurality of light-emitting units 12 located on a first side of the array substrate 11; and a planarization layer 13 located on a side of the plurality of light-emitting units 12 away from the array substrate 11. The array substrate 11 includes a control circuit 111, where the control circuit 111 corresponds to the light-emitting units 12 and is configured to control the emission state of its corresponding light-emitting unit 12. The planarization layer 13 is configured to provide a flat formation surface for the cover plate 30 or the polarizer 40.

Furthermore, as shown in FIG. 22, the present disclosure further provides a display device 100, where the display device includes any of the foregoing display modules. Since the relevant features of the display module have been described in detail in the foregoing embodiments, repeated description thereof is omitted herein for brevity.

In some embodiments of the present disclosure, the display device may be, but is not limited to, a mobile phone, a tablet computer, a wearable device, a vehicle-mounted device, an augmented reality (AR)/virtual reality (VR) device, a laptop computer, an ultra-mobile personal computer (UMPC), a netbook, or a personal digital assistant (PDA). The present disclosure impose no limitation in this regard.

In summary, as disclosed, the display module and the display device are configured such that, when the display module is in a bent state, the display module includes a bending region and a non-bending region. In a direction perpendicular to the plane of the display module, the groove at least partially overlaps with the bending region. Accordingly, during the bending process of the display module, the groove functions to block a jagged defect formed at the edge of the first adhesive layer due to energy fluctuation of a laser during cutting at the cutting position. This prevents the defect from propagating from the non-light-transmitting region of the display module to the light-transmitting region. As a result, the presence of such a jagged defect does not affect the display quality of the display module, thereby improving the bending reliability of the display module and enhancing the overall user experience.

Moreover, in the display module and the display device provided in the embodiments of the present disclosure, prior to bonding the protective cover plate to the display side of the display panel using the first adhesive layer, the first adhesive layer is subjected to laser cutting at a cutting position, such that the edge of the first adhesive layer is flush with the edge of the display panel. In other words, the first adhesive layer in the display module adopts an integrated edge-cutting design, so as to avoid the occurrence of wavy glue overflow at the edge of the first adhesive layer, and to reduce the probability of delamination between the protective cover plate and the display panel caused by repeated bending of the display module.

Therefore, it can be seen that the display module and the display device provided in the embodiments of the present disclosure may reduce the probability of delamination between the protective cover plate and the display panel due to repeated bending of the display module, without increasing the risk of display abnormalities in the display area of the display module, thereby enhancing the bending reliability of the display module and improving user experience.

The various embodiments described in this specification are presented in a progressive manner, a parallel manner, or a combination of both. Each embodiment primarily highlights the differences relative to other embodiments, and the same or similar features among the embodiments may be referred to mutually. For the device embodiments disclosed herein, since they correspond to the method embodiments, the descriptions are relatively simplified, and relevant details may be referenced from the descriptions of the method embodiments.

It should be understood that the descriptions of the embodiments and the drawings in the present disclosure are intended to be illustrative and not limiting. It should also be noted that relational terms such as “first” and “second” are used solely to distinguish one entity or operation from another and do not necessarily imply any actual relationship or order between such entities or operations. Furthermore, the terms “comprise,” “include,” or any other variation thereof are intended to cover non-exclusive inclusion, so that an article or device that includes a list of elements may also include other elements not expressly listed, or may include elements inherent to such article or device. Without further limitation, an element defined by the phrase “including a . . . ” does not exclude the presence of additional, identical elements in the article or device that includes the element.

The foregoing description of the disclosed embodiments enables those skilled in the art to make or use the present disclosure. Various modifications to these embodiments will be readily apparent to those skilled in the art, and the general principles defined herein may be applied to other embodiments without departing from the spirit or scope of the present disclosure. Therefore, the present disclosure is not to be limited to the embodiments disclosed herein, but is to be accorded the widest scope consistent with the principles and novel features disclosed herein.

What is claimed is:

1. A display module, comprising:
a display panel;
a protective cover plate located on a display side of the display panel, wherein a first region of the protective cover plate is a light-transmitting region, and a second region of the protective cover plate is a non-light-transmitting region, the second region surrounding the first region; and
a first adhesive layer located between the display panel and the protective cover plate, wherein the first adhesive layer comprises at least one groove, and in a direction perpendicular to a plane where the display module is located, the second region of the protective cover plate covers the at least one groove,
wherein, when the display module is in a bent state, the display module comprises a bending region and a non-bending region, and in the direction perpendicular to the plane where the display module is located, the at least one groove at least partially overlaps with the bending region.

2. The display module according to claim 1, wherein
the bending region of the display module comprises: a first bending region adjacent to the non-bending region, and a second bending region located on a side of the first bending region away from the non-bending region; and
in the direction perpendicular to the plane where the display module is located, the at least one groove overlaps with the first bending region.

3. The display module according to claim 2, wherein, when the display module is in the bent state, stress in the first bending region is greater than stress in the second bending region.

4. The display module according to claim 2, wherein the display module comprises at least one bending axis, an extending direction of the at least one bending axis is a first direction, an extending direction of the at least one groove is a second direction, and the first direction is different from the second direction.

5. The display module according to claim 4, wherein the first direction is perpendicular to the second direction.

6. The display module according to claim 4, wherein the display module comprises N bending axes, and the first adhesive layer comprises N sets of grooves each corresponding to one bending axis, wherein one of the N sets of grooves comprises the at least one groove, and N is an integer not less than 1.

7. The display module according to claim 6, wherein a length D of the at least one groove in a third direction satisfies D≥2×D₀+a first process tolerance, the first process tolerance comprising a process tolerance generated when the at least one groove is formed, D₀ being not less than a length of the first bending region in the third direction, and the third direction being perpendicular to the first direction.

8. The display module according to claim 7, wherein the length D of the at least one groove in the third direction ranges from 5 mm to 30 mm, and a center of the at least one groove in the third direction coincides with a center of the first bending region in the third direction.

9. The display module according to claim 7, wherein
the non-bending region of the display module comprises a first planar display region and a second planar display region, the bending region being located between the first planar display region and the second planar display region in a direction parallel to a display surface of the display panel;
the first bending region comprises a first sub-bending region and a second sub-bending region, the first sub-bending region being located between the first planar display region and the second bending region, and the second sub-bending region being located between the second planar display region and the second bending region;
the first sub-bending region and the second sub-bending region are both non-overlapping with a bending axis of the bending region; and
D₀ is not less than a distance from a side of the first sub-bending region away from the second sub-bending region to a side of the second sub-bending region away from the first sub-bending region.

10. The display module according to claim 6, wherein one set of the N sets of grooves comprises a first groove and a second groove, the first groove being located on a first side of the light-transmitting region of the display module, the second groove being located on a second side of the light-transmitting region of the display module, and the second side and the first side being on opposite sides of the light-transmitting region in the first direction.

11. The display module according to claim 1, wherein a distance L between the at least one groove and an edge of the first adhesive layer satisfies L≥L₀, L₀ being a value of a second process tolerance, the second process tolerance comprising an alignment tolerance occurring during formation of the first adhesive layer.

12. The display module according to claim 11, wherein the second process tolerance further comprises a process tolerance occurring during formation of the at least one groove.

13. The display module according to claim 11, wherein the alignment tolerance during formation of the first adhesive layer comprises an alignment tolerance between the first adhesive layer and the display panel during bonding.

14. The display module according to claim 11, wherein a width of an overlapping region of the second region of the protective cover plate and the first adhesive layer in a first direction is L₁, L=L₁/2, the first direction being an extending direction of a bending axis of the display module.

15. The display module according to claim 1, wherein the at least one groove is formed by a physical cutting process.

16. The display module according to claim 1, further comprising: a filling layer configured to fill the at least one groove, wherein the filling layer comprises a crack-arresting agent.

17. The display module according to claim 1, wherein the protective cover plate comprises:
a transparent film; and
a light-shielding layer, wherein the light-shielding layer is located on a partial area of the transparent film facing the display panel and corresponds to the second region of the protective cover plate.

18. The display module according to claim 1, further comprising: a polarizer located between the display panel and the protective cover plate, wherein the polarizer is bonded to the protective cover plate via the first adhesive layer or bonded to the display panel via the first adhesive layer.

19. The display module according to claim 1, wherein the at least one groove penetrates through the first adhesive layer.

20. A display device, comprising a display module, wherein the display module comprises:
a display panel;
a protective cover plate located on a display side of the display panel, wherein a first region of the protective cover plate is a light-transmitting region, and a second region of the protective cover plate is a non-light-transmitting region, the second region surrounding the first region; and
a first adhesive layer located between the display panel and the protective cover plate, wherein the first adhesive layer comprises at least one groove, and in a direction perpendicular to a plane where the display module is located, the second region of the protective cover plate covers the at least one groove,
wherein, when the display module is in a bent state, the display module comprises a bending region and a non-bending region, and in the direction perpendicular to the plane where the display module is located, the at least one groove at least partially overlaps with the bending region.
